(19) United States
(12) Patent Application Publication
(10) Pub. No.: US 2011/0210754 A1
(43) Pub. Date: Sep. 1, 2011

(54) CAPACITANCE SENSING MODULE AND ELECTRONIC APPARATUS

(75) Inventor: Hsin-Hung Shen, Taipei City (TW)

(73) Assignee: COMPAL ELECTRONICS, INC., Taipei City (TW)

(21) Appl. No.: 12/900,486

(22) Filed: Oct. 8, 2010

Related U.S. Application Data
(60) Provisional application No. 61/309,001, filed on Mar. 1, 2010.

(51) Int. Cl. G01R 27/26

(52) U.S. Cl. 324/686

(57) ABSTRACT

A capacitance sensing module adapted to an electronic apparatus having a first body and a second body hinged to the first body is provided. The capacitance sensing module includes a capacitance sensor and a metal conductor. The capacitance sensor is adapted to be fixed in the first body. The metal conductor is adapted to be fixed in the second body. When the metal conductor is moved towards the capacitance sensor along with the movement of the second body with respect to the first body and thus a capacitance sensed by the capacitance sensor changes, the capacitance sensor generates a command to start a default function of the electronic apparatus.

### CROSS-REFERENCE TO RELATED APPLICATION

This application claims the priority benefit of U.S. provisional application Ser. No. 61/309,001, filed on Mar. 1, 2010. The entirety of the above-mentioned patent application is hereby incorporated by reference herein and made a part of this specification.

### BACKGROUND

1. Field of the Invention

The invention relates to a sensing module. More particularly, the invention relates to a capacitance sensing module for sensing whether two bodies of an electronic apparatus are overlapped or approached to each other.

2. Description of Related Art

A notebook computer generally includes a main body and a display body hinged to the main body. During utilization, the display body is pivoted relative to the main body to a suitable angle, so as to facilitate an operation of a user. During transportation or storage, the display body is pivoted to be overlapped to the main body, i.e. the display body is closed to the main body, so as to reduce a space occupied by the notebook computer.

In order to get to know whether the display body is closed to the main body so as to activate a default function, for example, shutdown, standby and sleep, etc., a conventional method is to respectively set a magnet and a magnetic field sensor (i.e. a Hall sensor) in the display body and the main body. Therefore, when the display body is closed to the main body so that the magnet is moved towards the magnetic field sensor, the magnetic field sensor may sense a magnetic field variation generated by the magnet, so that it is known that the display body is closed to the main body.

However, sensitivity of the above method is determined by a number of magnetic poles and a magnetic intensity of the used magnet. To achieve a higher sensitivity, a better magnet has to be used, which may increase a component cost. Moreover, the magnet may influence a part of electronic devices in the main body.

### SUMMARY OF THE INVENTION

The invention is directed to a capacitance sensing module, which may have relatively low component cost and simple devices.

The invention is directed to an electronic apparatus, in which a capacitance sensing module may have relatively low component cost and simple devices.

The invention provides a capacitance sensing module adapted to an electronic apparatus having a first body and a second body hinged to the first body. The capacitance sensing module includes a capacitance sensor and a metal conductor. The capacitance sensor is adapted to be fixed in the first body. The metal conductor is adapted to be fixed in the second body. When the metal conductor is moved towards the capacitance sensor along with movement of the second body with respect to the first body and thus a capacitance sensed by the capacitance sensor changes, the capacitance sensor generates a command to start a default function of the electronic apparatus.

The invention provides an electronic apparatus including a first body, a second body hinged to the first body and a capacitance sensing module. The capacitance sensing module includes a capacitance sensor and a metal conductor. The capacitance sensor is fixed in the first body. The metal conductor is fixed in the second body. When the metal conductor is moved towards the capacitance sensor along with movement of the second body with respect to the first body and thus a capacitance sensed by the capacitance sensor changes, the capacitance sensor generates a command to start a default function of the electronic apparatus.

According to the above descriptions, in the invention, by sensing a variation of the capacitance sensed by the capacitance sensor that is caused by the metal conductor, it is determined whether the second body of the electronic apparatus is closed to the first body. Therefore, compared to the conventional technique that a relatively high-cost magnet has to be used to cause a magnetic field variation, in the invention, the metal conductor with a low cost is used to cause the capacitance variation, which may achieve a low component cost.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are schematic diagrams respectively illustrating an open state and a closed state of an electronic apparatus according to an embodiment of the invention.

FIG. 2A and FIG. 2B are schematic diagrams respectively illustrating a departure state and a close state of components of a capacitance sensing module of FIG. 1A.

### DETAILED DESCRIPTION OF DISCLOSED EMBODIMENTS

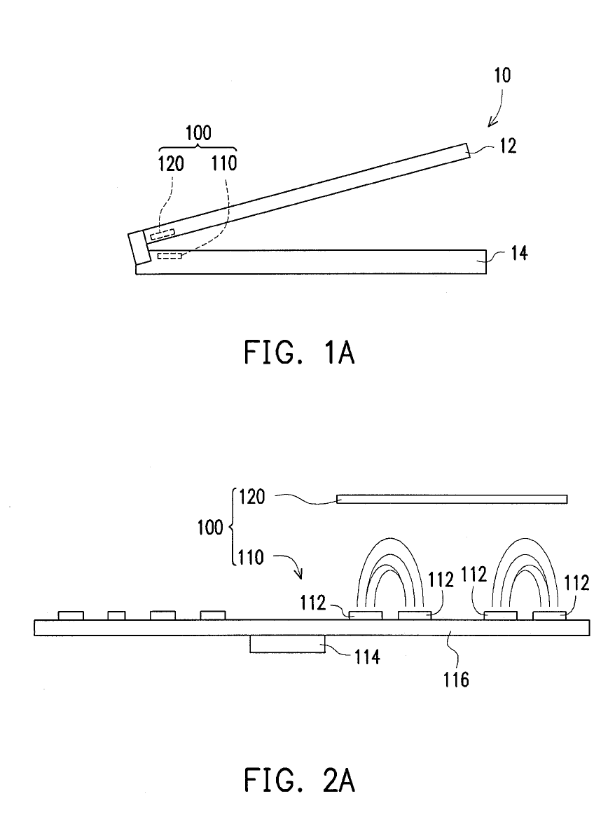

FIG. 1A and FIG. 1B are schematic diagrams respectively illustrating an open state and a closed state of an electronic apparatus according to an embodiment of the invention. Referring to FIG. 1A, the electronic apparatus 10 of the present embodiment includes a first body 12 and a second body 14, wherein the second body 14 is hinged to the first body 12. The electronic apparatus 10 is, for example, a notebook computer, and the first body 12 and the second body 14 can be a host body and a display body hinged to the first body of the notebook computer.

Moreover, the electronic apparatus 10 further includes a capacitance sensing module 100, which is used for determining whether the second body 14 is closed to the first body 12. The capacitance sensing module 100 includes a capacitance sensor 110 and a metal conductor 120, wherein the capacitance sensor 110 is fixed in the first body 12, and the metal conductor 120 is fixed in the second body 14.

Referring to FIG. 1A and FIG. 1B, when the metal conductor 120 is moved towards the capacitance sensor 110 along with movement of the second body 14 with respect to the first body 12 and thus a capacitance sensed by the capacitance sensor 110 changes, the capacitance sensor 110 generates a command, which represents that the second body 14 is closed to the first body 12, so as to start a default function of the electronic apparatus 10, for example, shutdown, standby and sleep, etc.

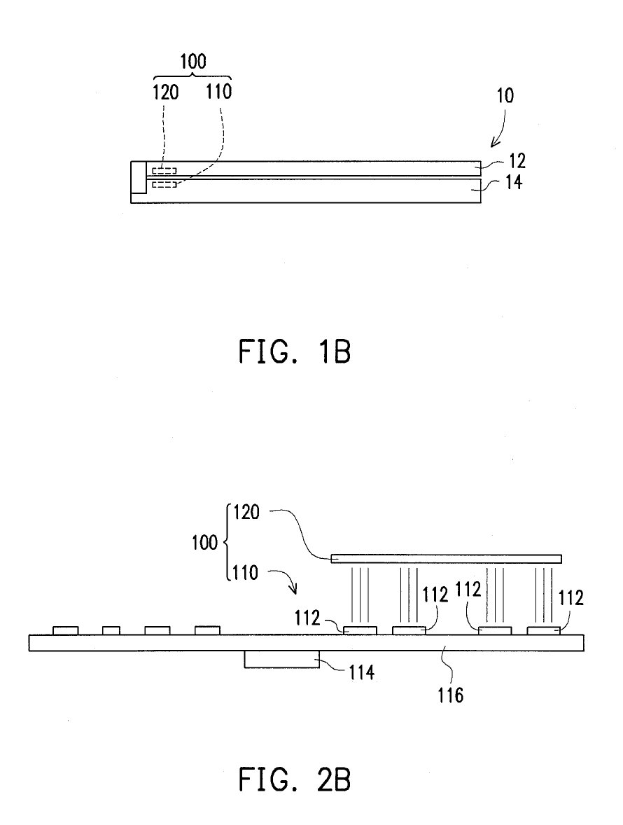

FIG. 2A and FIG. 2B are schematic diagrams respectively illustrating a departure state and a close state of the components of the capacitance sensing module of FIG. 1A. Referring to FIG. 2A, in the present embodiment, the capacitance sensor 110 includes at least one electrode pair 112 (two electrode pairs are illustrated in FIG. 2A) and a control device 114, wherein the control device 114 is coupled to the electrode pairs 112. When the capacitance sensed through the electrode pairs 112 changes, the control device 114 generates the command representing that the second body 14 is closed to the first body 12, so as to start the default function of the electronic apparatus 10.

Referring to FIG. 2A, when the metal conductor 120 is departed from the electrode pairs 112 (i.e. the second body 14 is opened relative to the first body 12 as that shown in FIG. 1A), media above each of the electrode pairs 112 is air, so that the sensed capacitance is relatively low. However, referring to FIG. 2B, when the metal conductor 120 is moved towards the electrode pairs 112 (i.e. the second body 14 is closed to the first body 12 as that shown in FIG. 1B), media above each of the electrode pairs 112 may include the metal conductor 120, so that the sensed capacitance is relatively high.

In the present embodiment, the capacitance sensor 110 may include a wiring board 116. The electrode pairs 112 and the control device 114 are disposed on the wiring board 116, and the control device 114 is coupled to the electrode pairs 112 through the wiring board 116.

In summary, in the invention, by sensing a variation of the capacitance sensed by the capacitance sensor that is caused by the metal conductor, it is determined whether the second body of the electronic apparatus is closed to the first body. Therefore, compared to the conventional technique that a relatively high-cost magnet has to be used to cause a magnetic field variation, in the invention, the metal conductor with a low cost is used to cause the capacitance variation, which may achieve a low component cost.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A capacitance sensing module, adapted to an electronic apparatus having a first body and a second body hinged to the first body, the capacitance sensing module comprising:
a capacitance sensor, adapted to be fixed in the first body; and
a metal conductor, adapted to be fixed in the second body,
wherein when the metal conductor is moved towards the capacitance sensor along with movement of the second body with respect to the first body and thus a capacitance sensed by the capacitance sensor changes, the capacitance sensor generates a command to start a default function of the electronic apparatus.

2. The capacitance sensing module as claimed in claim 1, wherein the capacitance sensor comprises:
an electrode pair; and
a control device, coupled to the electrode pair, wherein when the capacitance sensed through the electrode pair changes, the control device generates the command.

3. The capacitance sensing module as claimed in claim 2, wherein the capacitance sensor further comprises:
a wiring board, wherein the electrode pair and the control device are disposed on the wiring board, and the control device is coupled to the electrode pair through the wiring board.

4. An electronic apparatus comprising:
a first body;
a second body, hinged to the first body; and
a capacitance sensing module, comprising:
a capacitance sensor, fixed in the first body; and
a metal conductor, fixed in the second body,
wherein when the metal conductor is moved towards the capacitance sensor along with movement of the second body with respect to the first body and thus a capacitance sensed by the capacitance sensor changes, the capacitance sensor generates a command to start a default function of the electronic apparatus.

5. The electronic apparatus as claimed in claim 4, wherein the capacitance sensor comprises:
an electrode pair; and
a control device, coupled to the electrode pair, wherein when the capacitance sensed through the electrode pair changes, the control device generates the command.

6. The electronic apparatus as claimed in claim 5, wherein the capacitance sensor further comprises:
a wiring board, wherein the electrode pair and the control device are disposed on the wiring board, and the control device is coupled to the electrode pair through the wiring board.

7. The electronic apparatus as claimed in claim 5, wherein the first body and the second body are respectively a host body and a display body hinged to the host body of a notebook computer.
